(19) United States
(12) Patent Application Publication
(10) Pub. No.: US 2008/0029826 A1
(43) Pub. Date: Feb. 7, 2008

(54) Semicondutor memory device and method of manufacturing the same

(75) Inventors: Hiroyuki Suzuki, Gunma (JP); Koichi Yamada, Gifu (JP); Yutaka Yamada, Gunma (JP)

Correspondence Address: MORRISON & FOERSTER LLP, 1650 TYSONS BOULEVARD, SUITE 400, MCLEAN, VA, 22102, US

(73) Assignee: SANYO ELECTRIC CO., LTD., Osaka (JP)

(21) Appl. No.: 11/727,876

(22) Filed: Mar. 28, 2007

(30) Foreign Application Priority Data
Mar. 28, 2006 (JP) 2006-088906

(51) Int. Cl. H01L 29/76; H01L 21/336

(52) U.S. Cl. 257/390; 438/297; 257/E29.226; 257/E21.409

(57) ABSTRACT

The invention provides a semiconductor memory device which achieves memory size reduction. This memory is formed on a surface of a p-type silicon substrate, and includes an n-type impurity region serving as a cathode of a diode included in a memory cell and a word, a plurality of p-type impurity regions formed on a surface of the n-type impurity region at predetermined intervals and each serving as an anode of the diode, a bit line formed on the p-type silicon substrate and connected with the p-type impurity region, and a wiring layer provided in a lower layer than the bit line and connected with the n-type impurity region at predetermined intervals.

### CROSS-REFERENCE OF THE INVENTION

This invention claims priority from Japanese Patent Application No. 2006-088906, the content of which is incorporated herein by reference in its entirety.

### BACKGROUND OF THE INVENTION

1. Field of the Invention

The invention relates to a semiconductor memory device, particularly to a semiconductor memory device such as a mask ROM.

2. Description of the Related Art

Conventionally, mask ROM devices have been known as an example of the semiconductor memory device. FIG. 12 is a plan layout view showing a structure of a mask ROM according to a conventional contact method. FIG. 13 is a cross-sectional view of the mask ROM according to the conventional contact method shown in FIG. 12 along line 500-500. Referring to FIGS. 12 and 13, in the mask ROM according to the conventional contact method, a plurality of impurity regions 202 where an impurity is diffused is formed at predetermined intervals on an upper surface of a substrate 201. Word lines 204 which serve as gate electrodes are formed on the upper surface of the substrate 201 with intervening insulation films 203 between the adjacent two impurity regions 202 respectively. The word line 204, the gate insulation film 203, and the corresponding two impurity regions 202 configurate a transistor 205. A first interlayer insulation film 206 is formed so as to cover the upper surface of the substrate 201 and the word lines 204. Contact holes 207 are formed in this first interlayer insulation film 206 in positions corresponding to the impurity regions 202 respectively, and first plugs 208 are embedded in the contact holes 207 respectively, being connected with the impurity regions 202.

Source lines (GND lines) 209 and connection layers 210 are provided on the first interlayer insulation film 206, being connected with the plugs 208 respectively. It is noted that one transistor 205 is provided in each of memory cells 211. A second interlayer insulation film 212 is formed on the first interlayer insulation film 206 so as to cover the source lines (GND lines) 209 and the connection layers 210. Contact holes 213 are formed in this second interlayer insulation film 212 in predetermined regions above the connection layers 210, and second plugs 214 are embedded in the contact holes 213 respectively.

Connection layers 219 are provided on the second interlayer insulation film 212, being connected with the plugs 214 respectively. A third interlayer insulation film 216 is formed on the second interlayer insulation film 212 so as to cover the connection layers 219. Contact holes 217 are formed in this third interlayer insulation film 216 in predetermined regions above the connection layers 219, and third plugs 218 are embedded in these contact holes 217. Bit lines 215 are formed on the third interlayer insulation film 216, being connected with the plugs 218. The bit lines 215 and the impurity regions 202 of the transistors 205 are thus connected.

In the mask ROM according to the conventional contact method, whether or not the transistor 205 is connected with (contacts) the bit line 215 depends on the formation or nonformation of the third contact hole 217. Furthermore, the data of the memory cell 211 having the transistor 205 is set to “0” or “1” depending on whether or not the transistor 205 is connected with the bit line 215.

The relevant technology is described in Japanese Patent Application Publication No. H05-275656, for example. However, since the conventional mask ROM shown in FIG. 13 has one transistor 205 in each of the memory cells 211, there is a problem that memory cell size is large.

### SUMMARY OF THE INVENTION

The invention provides a semiconductor memory device including: a semiconductor substrate; a plurality of memory cells, each of the memory cells comprising a first impurity region of a first conductivity type formed on a surface of the semiconductor substrate and a second impurity region of a second conductivity type formed on the surface of the semiconductor substrate and contacting the first impurity region; a bit line formed on the semiconductor substrate; and a wiring formed under the bit line and connected with the first impurity region; wherein the second impurity region in each of the plurality of memory cells is selectively connected with the bit line.

### BRIEF DESCRIPTION OF THE DRAWINGS

FIG. 1 is a circuit diagram of a semiconductor memory device of a first embodiment of the invention.

FIG. 2 is a plan view of the semiconductor memory device of the first embodiment of the invention.

FIGS. 3 to 5 are cross-sectional views of the semiconductor memory device of the first embodiment of the invention.

FIGS. 6 to 9 are cross-sectional views showing a method of manufacturing the semiconductor memory device of the first embodiment of the invention.

FIG. 10 is a cross-sectional view of a semiconductor memory device of a second embodiment of the invention.

FIG. 11 is a cross-sectional view showing a method of manufacturing the semiconductor memory device of the second embodiment of the invention.

FIG. 12 is a plan view of a conventional semiconductor memory device.

FIG. 13 is a cross-sectional view of the conventional semiconductor memory device.

### DETAILED DESCRIPTION OF THE INVENTION

An embodiment of the invention will be described referring to figures. In the following description of the embodiment, a mask ROM will be taken for an example of a semiconductor memory device of the invention.

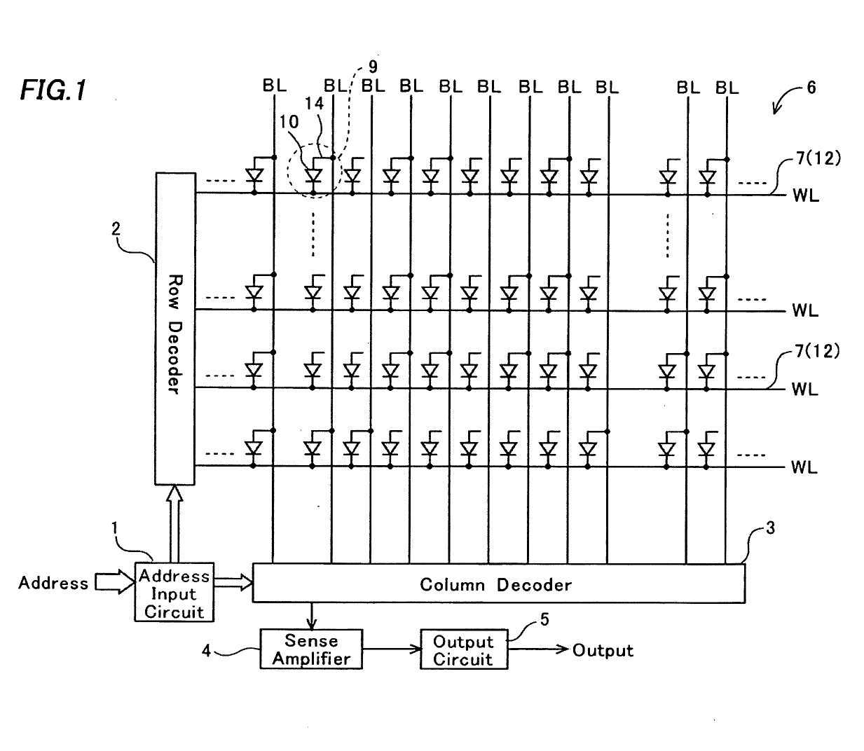

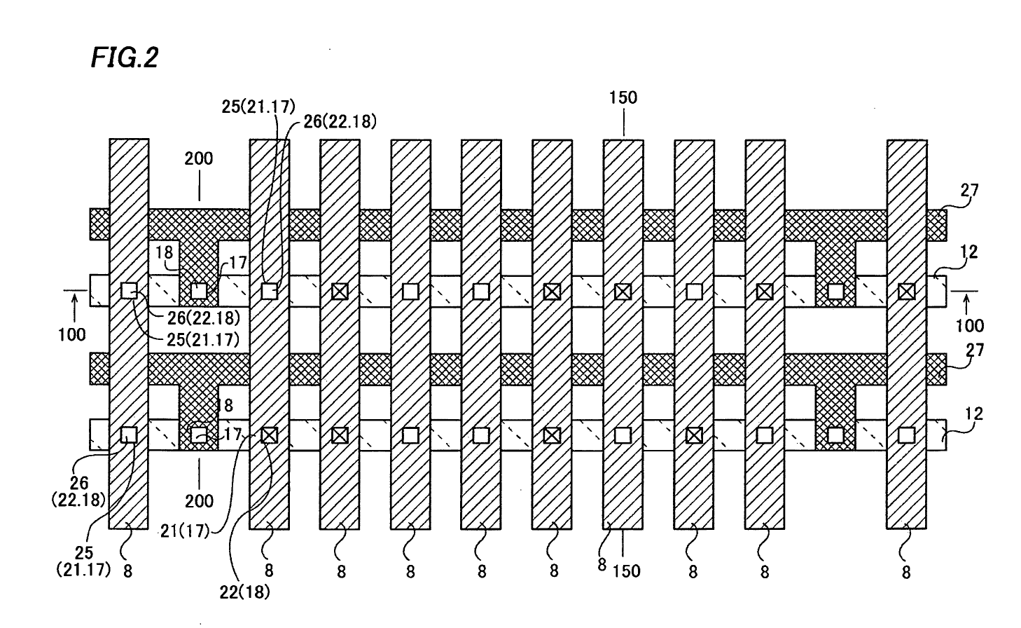

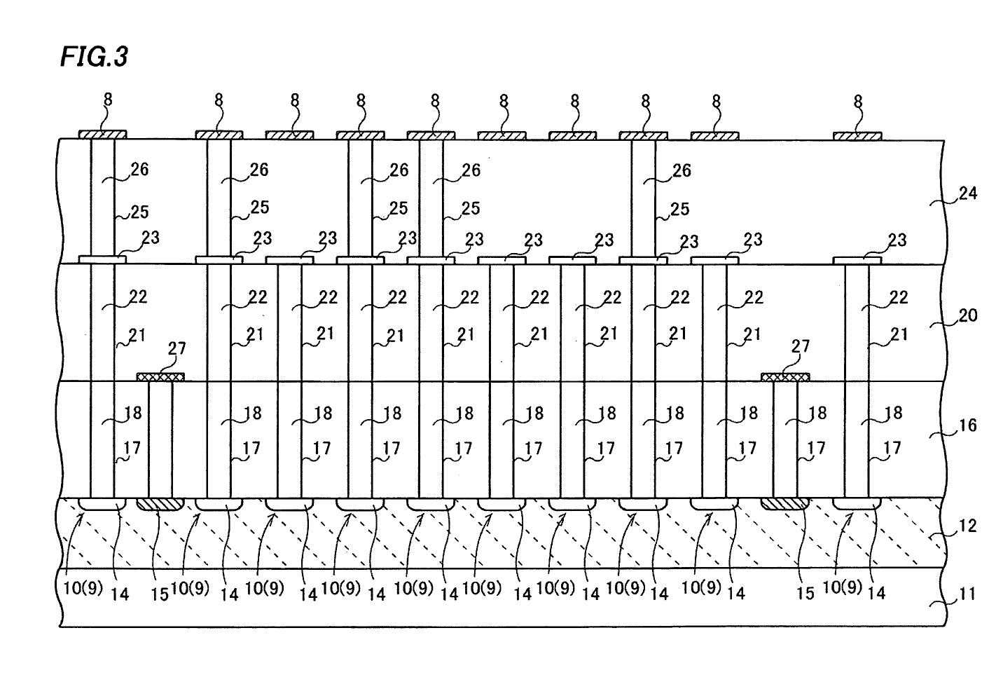

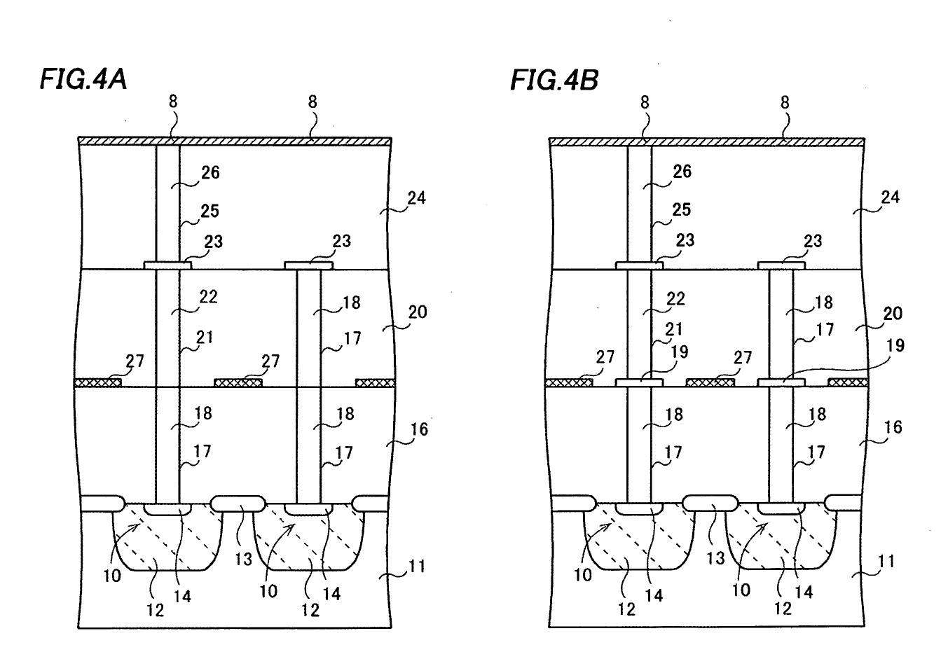

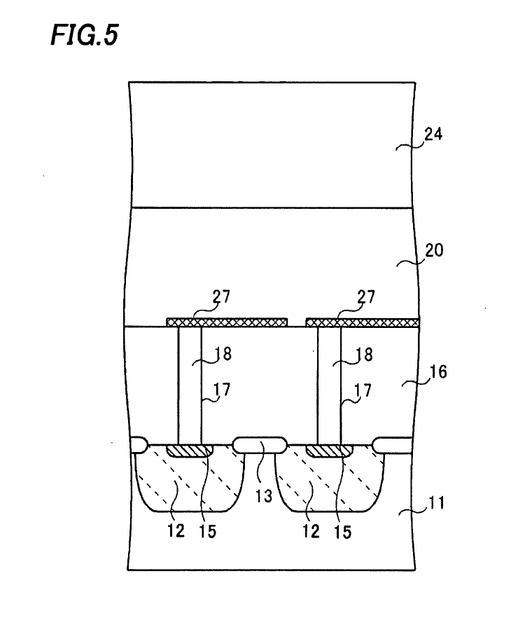

FIG. 1 is a circuit diagram showing a structure of a mask ROM of a first embodiment. FIG. 2 is a plan layout view showing a structure of a memory cell array region of the mask ROM of the first embodiment shown in FIG. 1. FIG. 3 is a cross-sectional view of the memory cell array region of the mask ROM of the first embodiment shown in FIG. 2 along line 100-100. FIGS. 4A and 4B are cross-sectional views of the memory cell array region of the mask ROM of the first embodiment shown in FIG. 2 along line 150-150. FIG. 5 is a cross-sectional view of the memory cell array region of the mask ROM of the first embodiment shown in FIG. 2 along line 200-200. First, the structure of the mask ROM of the first embodiment will be described referring to FIGS. 1 to 5.

The mask ROM of the invention has an address input circuit 1, a row decoder 2, a column decoder 3, a sense amplifier 4, an output circuit 5, and a memory cell array region 6, as shown in FIG. 1. The address input circuit 1, the row decoder 2, the column decoder 3, the sense amplifier 4 and the output circuit 5 form a peripheral circuit. Transistors (not shown) each having a gate electrode made of a polysilicon layer are provided in the peripheral circuit. The address input circuit 1 is configured to output address data to the row decoder 2 and the column decoder 3 when receiving a predetermined address from outside. A plurality of word lines (WL) 7 is connected with the row decoder 2. When the address data is inputted to the row decoder 2 from the address input circuit 1, the row decoder 2 selects the word line 7 corresponding to the inputted address data, turns the potential of the word line 7 to L level (GND=0V), and turns the potential of the other word lines 7 than the selected word lines 7 to H level (Vcc).

A plurality of bit lines (BL) 8 is connected with the column decoder 3, being disposed perpendicularly crossing the word lines (WL) 7. When the address data is inputted to the column decoder 3 from the address input circuit 1, the column decoder 3 selects the bit line 8 corresponding to the inputted address data and connects the selected bit line 8 to the sense amplifier 4. The sense amplifier 4 is of a current sense type, detects a current flowing through the bit line 8 selected by the column decoder 3, and outputs a H level signal when a current higher than a predetermined value inclusive flows through the selected bit line 8 and outputs a L level signal when a current lower than the predetermined value flows through the selected bit line 8. The output circuit 5 is configured to output a signal to outside when receiving the output of the sense amplifier 4.

A plurality of memory cells 9 is disposed in a matrix in the memory cell array region 6. These memory cells 9 are respectively disposed at intersections of the plurality of word lines 7 and bit lines 8 which are disposed perpendicularly crossing each other. A cross-point type mask ROM is thus formed in the first embodiment. The memory cells 9 each including a diode 10 of which an anode is connected with the bit line 8 and the memory cells 9 each including a diode 10 of which an anode is not connected with the bit line 8 are provided in the memory cell array region 6.

In the memory cell array region 6, as shown in FIGS. 2 to 5, n-type impurity regions 12 are formed on an upper surface of a p-type silicon substrate 11, extending in a predetermined direction. This p-type silicon substrate 11 is an example of a “semiconductor substrate” of the invention, and the n-type impurity regions 12 are an example of a “first impurity region” of the invention. The plurality of n-type impurity regions 12 is formed at predetermined intervals in a direction perpendicular to those longitudinal directions. As shown in FIGS. 4 and 5, element isolation insulation films 13 each for separating the adjacent two n-type impurity regions 12 are formed between the adjacent n-type impurity regions 12, respectively. It is noted that conductivity types, such as n⁺-type, n-type and n⁻-type, belong to a general conductivity type, and conductivity types, such as p⁺-type, p-type and p⁻-type, belong to another general conductivity type.

As shown in FIG. 3, a plurality of p-type impurity regions 14 is formed in one n-type impurity region 12 at predetermined intervals in the longitudinal direction of the n-type impurity region 12. These p-type impurity regions 14 are an example of a “second impurity region” of the invention. One p-type impurity region 14 and the n-type impurity region 12 form the diode 10 of the memory cell 9. With this structure, the n-type impurity region 12 serves as a common cathode of the plurality of diodes 10 and the p-type impurity region 14 serves as an anode of the diode 10. In the first embodiment, the n-type impurity region 12 also serves as the word line (WL) 7 (see FIG. 1). Furthermore, one n-type contact region 15 is formed at intervals of eight p-type impurity regions 14 in the n-type impurity region 12. This n-type contact region 15 contains a higher concentration of impurity than the n-type impurity region 12, and is provided for reducing the contact resistance between a first plug 18 which will be described below and the n-type impurity region 12 of the p-type silicon substrate 11.

A first interlayer insulation film 16 is provided so as to cover the upper surface of the p-type silicon substrate 11. Contact holes 17 are provided in the first interlayer insulation film 16 in regions corresponding to the p-type impurity regions 14 and the n-type contact regions 15. First plugs 18 made of W (tungsten) are embedded in the contact holes 17, respectively. Thus, the first plugs 18 are connected with the p-type impurity regions 14 and the n-type contact regions 15, respectively.

In this embodiment, pads are not formed between the first plugs 18 and second plugs 22 which will be described below. Therefore, as shown in FIG. 4A, wide spaces are formed on the first interlayer insulation film 16 in regions above the p-type impurity regions 14. Therefore, wiring layers 27 made of Al are formed in these spaces so as to extend in the longitudinal direction of the n-type impurity regions 12 and be connected with the first plugs 18. As shown in FIG. 4A, the plurality of wiring layers 27 is formed at predetermined intervals in a direction perpendicular to the longitudinal direction thereof above the element isolation insulation films 13. As shown in FIG. 4B, even when first pads 19 are formed between the first plugs 18 and the second plugs 22 which will be described below, the spaces for forming the wiring layers 27 may be obtained depending on the miniaturization level of the memory. However, in this case, it is necessary to provide a sufficient space to prevent interference between the wiring layers 27 and the first pads 19.

As shown in FIGS. 2 and 5, the wiring layers 27 are formed so as to extend onto regions corresponding to the n-type contact regions 15 on the first interlayer insulation film 16, and connected with the first plugs 18 on the n-type contact regions 15. Therefore, the wiring layers 27 and the n-type impurity regions 12 are connected at intervals of eight memory cells (at predetermined intervals). When the word line 7 corresponding to the address data inputted to the row decoder 2 (see FIG. 1) is to be selected, the potential of the selected word line 7 (the n-type impurity region 12) is turned to L level (GND) and the potential of an unselected word line 7 (the n-type impurity region 12) is turned to H level (Vcc) through the wiring layers 27.

A second interlayer insulation film 20 is provided on the first interlayer insulation film 16 so as to cover the wiring layers 27. Contact holes 21 are formed in this second interlayer insulation film 20 in regions corresponding to the first plugs 18 on the p-type impurity regions 14. Second plugs 22 made of W are embedded in the contact holes 21. Furthermore, second pad layers 23 made of Al are formed on the second interlayer insulation film 20 in regions corresponding to the second plugs 22. These second pad layers 23 are formed into almost square shapes in the plan view. The second plugs 22 and the second pad layers 23 are connected with each other.

A third interlayer insulation film 24 is provided on the second interlayer insulation film 20 so as to cover the second pad layers 23. Contact holes 25 are provided in this third interlayer insulation film 24 in regions corresponding to the second pad layers 23, and third plugs 26 made of W are embedded in the contact holes 25. These contact holes 25 are an example of a “connection hole” of the invention. A plurality of bit lines (BL) 8 made of Al is formed on the third interlayer insulation film 24 at predetermined intervals. The bit lines (BL) 8 are formed so as to extend in the direction perpendicular to the longitudinal direction of the n-type impurity regions 12 as shown in FIG. 2, and disposed so as to cross the n-type impurity regions 12 at regions corresponding to the diodes 10 of the memory cells 9 (see FIG. 3).

Depending on whether or not the contact hole 25 is formed between the second pad layer 23 and the bit line (BL) 8 corresponding to the diode 10 of the memory cell 9, the data of the memory cell 9 is changed. In detail, the data of the memory cell 9 is set to “1” when the bit line (BL) 8 and the p-type impurity region 14 forming the diode 10 of the memory cell 9 are connected through the plug 26 embedded in the contact hole 25, the second pad layer 23, the second plug 22, and the first plug 18 by the formation of the contact hole 25 corresponding to the diode 10 of the memory cell 9. On the other hand, the data of the memory cell 9 is set to “0” when the diode 10 of the memory cell 9 and the corresponding bit line (BL) 8 are not connected with each other by nonformation of the contact hole 25 corresponding to the diode 10 of the memory cell 9.

In this manner, in the memory of the first embodiment, the structure under the second interlayer insulation film 20 does not depend on the data of the memory cell. This realizes the manufacture and stock of the structure at least under the second interlayer insulation film 20 before receipt of order. Therefore, after receiving an order, the manufacturing process is started from the formation of the contact holes 25 for writing the data of the memory cells, thereby largely reducing time to shipment.

Next, referring to FIGS. 1 and 2, the operation of the mask ROM of the first embodiment will be described. First, a predetermined address is inputted to the address input circuit 1 (see FIG. 1). Thus, address data corresponding to the inputted address is outputted from the address input circuit 1 to the row decoder 2 and the column decoder 3. Then, the address data are decoded by the row decoder 2, and a predetermined word line 7 corresponding to the address data is selected. Then, the potential of the selected word line 7 (the n-type impurity region 12) is turned to L level (GND) through the wiring layer 27 (see FIG. 2) and the potential of an unselected word line 7 is turned to H level (Vcc) through the wiring layer 27 (see FIG. 2).

On the other hand, at the column decoder 3 receiving the address data from the address input circuit 1 (see FIG. 1), a predetermined bit line 8 corresponding to the inputted address data is selected and connected to the sense amplifier 4. Then, the potential near Vcc is supplied from the sense amplifier 4 to the selected bit line 8. Then, a current flows from the sense amplifier 4 to the word line 7 through the bit line 8 and the diode 10 in a case where the anode of the diode 10 of the selected memory cell 9 positioned at the intersection of the selected word line 7 and the selected bit line 8 is connected with the bit line 8. At this time, the sense amplifier 4 detects a current higher than a predetermined value flowing through the bit line 8, and outputs a H level signal. Then, the output circuit 5 receives the output signal of the sense amplifier 4 and outputs a H level signal to outside.

On the other hand, a current does not flow from the bit line 8 to the word line 7 in a case where the anode of the diode 10 of the selected memory cell 9 positioned at the intersection of the selected word line 7 and the selected bit line 8 is not connected with the bit line 8. In this case, the sense amplifier 4 detects no current flowing and outputs a L level signal. The output circuit 5 receives the output signal of the sense amplifier 4 and outputs a L level signal to outside.

FIGS. 4 to 9 are cross-sectional views for explaining a process of manufacturing the memory cell array region of the mask ROM of the first embodiment of the invention. Referring to FIGS. 2 to 9, the process of manufacturing the memory cell array region of the mask ROM of the first embodiment will be described next.

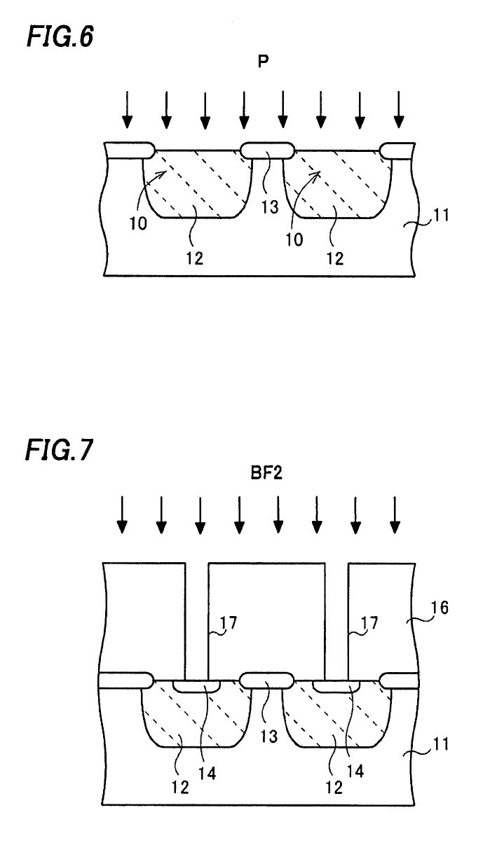

First, as shown in FIG. 6, the element isolation insulation films 13 made of a LOCOS (Local Oxidation of Silicon) film are formed on the upper surface of the p-type silicon substrate 11. Then, the gate insulation films (not shown) of the transistors (not shown) included in the described peripheral circuit are formed, and the polysilicon layers (not shown) forming the gate electrodes of the transistors are formed on the gate insulation films. Then, P (phosphorus) is ion-implanted in the p-type silicon substrate 11 under the condition of implantation energy of about 100 keV and a dose of about 3.5×10¹³ cm⁻². By this process, then-type impurity regions 12 are formed in the p-type silicon substrate 11, being separated by the element isolation insulation films 13.

Then, as shown in FIG. 7, the first interlayer insulation film 16 is formed so as to cover the whole surface. Then, the contact holes 17 are formed in the first interlayer insulation film 16 in the regions corresponding to the n-type impurity regions 12 by photolithography and etching processes. Then, a resist film (not shown) is formed so as to cover the first interlayer insulation film 16 except above regions to be formed with the n-type contact regions 15 (see FIG. 3). Then, P (phosphorus) is ion-implanted in the n-type impurity regions 12 through the contact holes 17 under the condition of implantation energy of about 25 keV and a dose of about 3.0×10¹⁴ cm⁻². The n-type contact regions 15 are formed by this process. Then, this resist film (not shown) is removed.

Then, a resist film (not shown) is formed so as to cover the first interlayer insulation film 16 except above regions to be formed with the p-type impurity regions 14 (see FIG. 7). Then, BF₂ is ion-implanted in the n-type impurity regions 12 through the contact holes 17 under the condition of implantation energy of about 40 keV and a dose of about 2.0×10¹⁵ cm⁻². The plurality of p-type impurity regions 14 are formed in the n-type impurity regions 12 by this process. The plurality of p-type impurity regions 14 and the n-type impurity region 12 form the plurality of diodes 10. Then, this resist film (not shown) is removed.

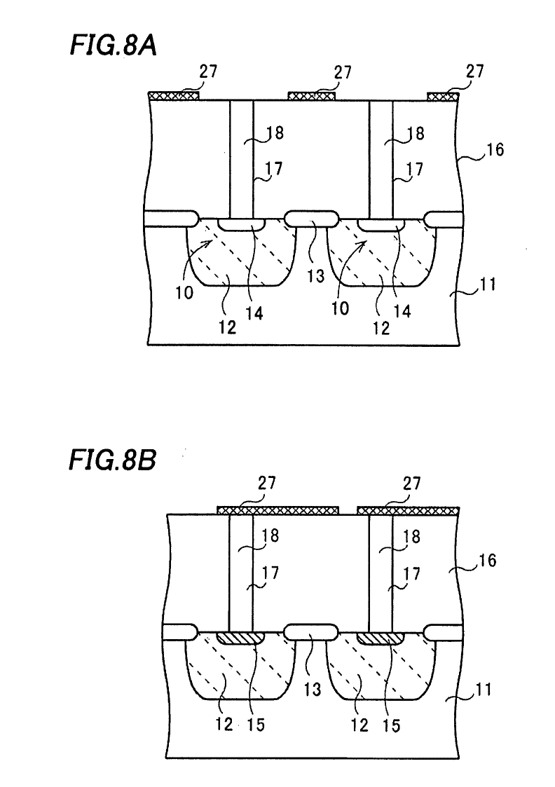

Then, as shown in FIGS. 8A and 8B, the first plugs 18 made of W are embeddedly formed in the contact holes 17. By this process, the first plugs 18 are respectively connected to the p-type impurity regions 14 (see FIG. 8A) and the n-type contact regions 15 (see FIG. 8B). Then, the wiring layers 27 made of Al are formed on the first interlayer insulation film 16 in regions corresponding to the element isolation films 14 by photolithography and etching processes so as to extend in the longitudinal direction of the n-type impurity regions 12. At this time, as shown in FIG. 8B, the wiring layers 27 are formed so as to extend onto the regions corresponding to the n-type contact regions 15. By this, the wiring layers 27 and the n-type impurity regions 12 are connected to each other through the first plugs 18 and the n-type contact regions 15.

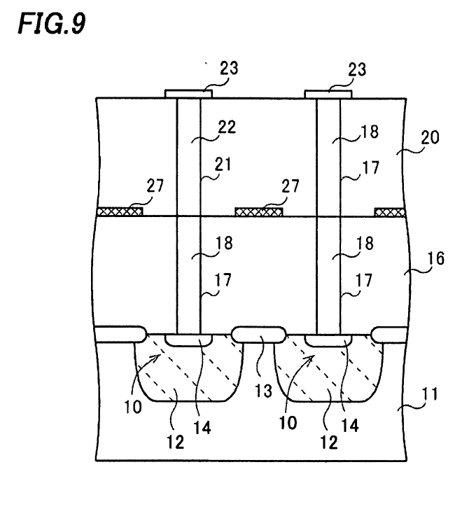

Then, as shown in FIG. 9, the second interlayer insulation film 20 is formed on the first interlayer insulation film 16 so as to cover the wiring layers 27. Then, the contact holes 21 are formed in the regions corresponding to the first plugs 18 on the p-type impurity regions 14. Then, the second plugs 22 made of W are embedded in the contact holes 21. Then, the second pad layers 23 made of Al are formed on the second interlayer insulation film 20 so as to be connected to the second plugs 22 by photolithography and etching processes. At this time, the second pad layers 23 are formed into almost square shapes in the plan view. It is noted that the structure formed here does not depend on the data of the memory cells. This realizes the manufacture and stock of this structure before receiving an order. This largely reduces time to shipment from receipt of order.

Then, as shown in FIG. 4A, the third interlayer insulation film 24 is formed on the second interlayer insulation film 20 so as to cover the second pad layers 23. Then, the contact holes 25 are formed in the regions corresponding to the second plugs 26 above the p-type impurity regions 14. Then, the third plugs 26 made of W are embedded in the contact holes 25. At this time, according to the data of the memory cells of the order, when the p-type impurity region 14 as the anode of the diode 10 is to be connected to the bit line 8, the contact hole 25 and the third plug 26 are provided. On the other hand, the p-type impurity region 14 as the anode of the diode 10 is not to be connected to the bit line 8, the contact hole 25 and the third plug 26 are not provided.

Then, the plurality of bit lines 8 made of Al is formed on the third interlayer insulation film 24 by photolithography and etching processes so as to extend in the direction perpendicular to the longitudinal direction of the n-type impurity regions 12. The plurality of bit lines 8 is formed at predetermined intervals so as to cross the regions corresponding to the p-type impurity regions 14. By this process, in the region where the third plug 26 is provided, the bit line 8 and the p-type impurity region 14 as the anode of the diode 10 are connected to each other through the third plug 26, the second pad 23, the second plug 22, and the first plug 18. On the other hand, in the region where the third plug 26 is not provided, the bit line 8 and the second pad layer 23 are not connected, so that the bit line 8 and the p-type impurity region 14 as the anode of the diode 10 are not connected to each other. Thus, the diode 10 corresponding to the data “1”, of which the anode is connected with the bit line 8, and the diode 10 corresponding to the data “0”, of which the anode is not connected with the bit line 8, are formed.

As described above, in the first embodiment, the diodes 10 each including the n-type impurity region 12 and the p-type impurity region 14 are formed on the upper surface of the p-type silicon substrate 11 and these diodes 10 are arrayed in a matrix, thereby forming the cross-point type mask ROM. Accordingly, since each of the memory cells 9 of the cross-point type mask ROM is configured to include one diode 10, the memory cell size is reduced compared with the conventional mask ROM where each of the memory cells includes one transistor.

Furthermore, by connecting the first plugs 18 and the second plugs 22 without through pads, the wide spaces are formed on the first interlayer insulation film 16 in the regions corresponding to the element isolation insulation films 13. Therefore, utilizing these spaces, the wiring layers 27 are formed on the first interlayer insulation film 16 in the regions corresponding to the element isolation insulation films 13. This prevents the blocking of the formation of the wiring layers 27 extending in the longitudinal direction of the n-type impurity regions 12. Furthermore, this eliminates a problem of interference between the wiring layers 27 and the pads. It is noted that each space between the n-type impurity regions 12 may become wide depending on the miniaturization level required for the memory. In this case, the wiring layers 27 may be formed even when the pads are formed between the first plugs 18 and the second plugs 22.

Furthermore, by driving stakes of the wiring layers 27 for the n-type impurity regions 12 serving as the word lines 7 at predetermined intervals, the increase of resistance due to the increase of the lengths of the n-type impurity regions 12 is prevented, thereby preventing the reduction of the turn-off (turn-on) speed of the word lines 7.

Furthermore, since the data of the memory cell 9 is set to “1” or “0” depending on the formation or nonformation of the contact hole 25 and the plug 26 in the third layer under the bit line 8 corresponding to the region formed with the memory cell 9, the contact hole 25 and the plug 26 connecting the bit line 8 and the p-type impurity region 14, the structure under the second interlayer insulation film 20 is manufactured and stored before receipt of order. Therefore, after receiving an order, the manufacturing process is started from the formation of the contact holes 25 for writing the data of the memory cells, thereby achieving the large reduction of time to shipment.

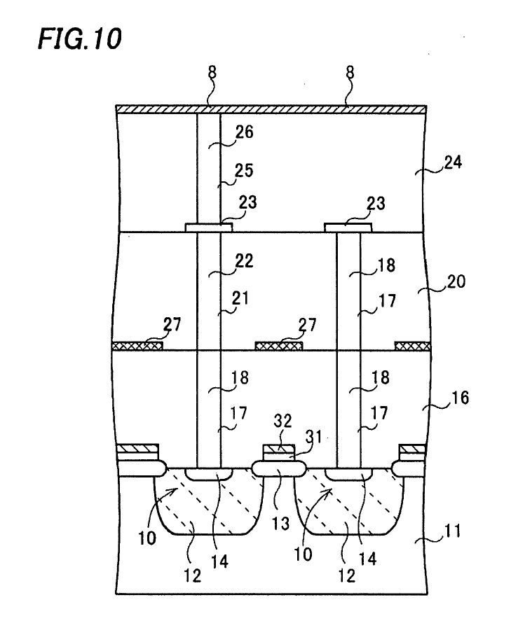

Next, a structure of a mask ROM of a second embodiment of the invention will be described. FIG. 10 is a cross-sectional view of a memory cell array region of the mask ROM of the second embodiment corresponding to the sectional view at line 150-150 of FIG. 2.

In the mask ROM of the second embodiment, as shown in FIG. 10, differing from the described first embodiment, polysilicon layers 31 having thicknesses of about 200 nm are formed on the element isolation insulation films 13 made of LOCOS films in the memory cell array region, and hard masks 32 made of SiO₂ films having thicknesses of about 180 nm are also formed on the polysilicon layers 31. The polysilicon layers 31 are grounded and the potentials thereof are fixed to 0V. These polysilicon layers 31 are an example of a “semiconductor layer” of the invention. The polysilicon layers 31 are formed by pattering the same polysilicon layer (not shown) forming the gate electrodes of the transistors (not shown) provided in the peripheral circuit. The other structure of the mask ROM of the second embodiment is the same as the structure of the mask ROM of the described first embodiment.

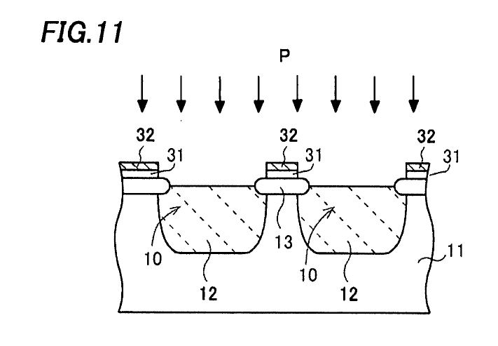

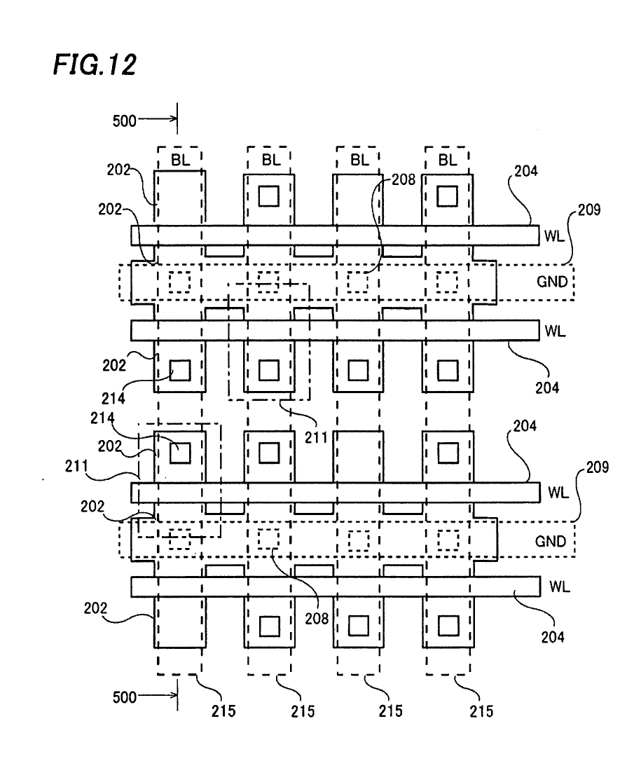

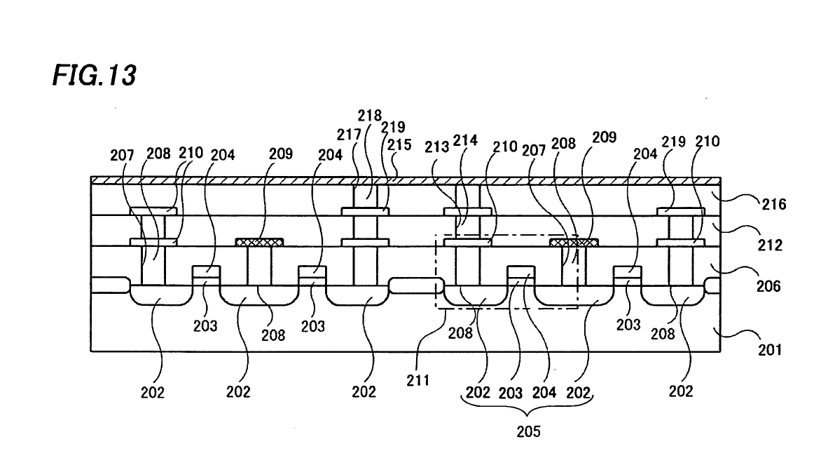

FIG. 11 is a cross-sectional view for describing a process of manufacturing the memory cell array region of the mask ROM of the second embodiment of the invention. Referring to FIGS. 10 and 11, the process of manufacturing the memory cell array region of the mask ROM of the second embodiment of the invention will be described next.

In the second embodiment, first, the element isolation insulation films 13 are formed on the upper surface of the p-type silicon substrate 11 by the same process as in the first embodiment. At this time, in the second embodiment, cleaning time is increased compared with that in the first embodiment to form the thinner element isolation insulation films 13. For example, while the element isolation insulation films 13 are removed by about 250 Å in the usual cleaning time, the films 13 are removed by about 550 Å in this embodiment. As a result, while the element isolation insulation films 13 are usually formed to have thicknesses of about 2300 Å, the films 13 are formed to have thicknesses of about 2000 Å in this embodiment. Then, in the second embodiment, as shown in FIG. 11, the polysilicon layers 31 having thicknesses of about 200 nm are formed on the element isolation insulation films 13 in the memory cell array regions by photolithography and etching processes. At this time, the polysilicon layers 31 in the memory cell array region and the polysilicon layer (not shown) forming the gate electrodes of the transistors (not shown) provided in the peripheral circuit are formed by patterning the same polysilicon layer. Furthermore, at this time, the hard masks 32 made of SiO₂ films having thicknesses of about 180 nm are simultaneously formed on the polysilicon layers 31 in the memory cell array region.

Then, P (phosphorus) is ion-implanted in the p-type silicon substrate 11 under the condition of the implantation energy of about 120 keV and a dose of about 3.5×10¹³ cm⁻² where the acceleration voltage is higher than the first embodiment. At this time, in the second embodiment, the polysilicon layers 31 and the hard masks 32 prevent P (phosphorus) as the n-type impurity from being implanted in the regions under the element isolation insulation films 13 in the p-type silicon substrate 11 in the memory cell array region. By this process, the plurality of n-type impurity regions 12 are formed in the p-type silicon substrate 11 in the memory cell array region, being separated by the element isolation insulation films 13. Furthermore, as described above, the element isolation insulation films 13 are formed thinner in the second embodiment. Furthermore, the acceleration voltage of the ion implantation is increased. Therefore, P (phosphorus) easily penetrates portions of the element isolation insulation films 13 uncovered with the polysilicon layers 31 and the hard masks 32. That is, the area of each of the n-type impurity regions 12 expanding under the element isolation insulation films 13 is easily controlled by the width of the polysilicon layer 31 and the hard mask 32.

Then, the mask ROM of the second embodiment is formed by the same processes as the described processes of the first embodiment shown in FIGS. 4 to 9.

In the second embodiment, as described above, when the n-type impurity regions 12 are formed by ion-implanting the impurity by providing the polysilicon layers 31 and the hard masks 32 on the element isolation insulation films 13 each for separating the adjacent two n-type impurity regions 12, the polysilicon layers 31 and the hard masks 32 prevent the n-type impurity from penetrating the element isolation insulation films 13 and reaching the surface of the p-type silicon substrate 11. This prevents a problem of the connection of each adjacent two n-type impurity regions 12 due to the n-type impurity reaching the p-type silicon substrate 11 under the element isolation insulation films 13.

In the second embodiment, the polysilicon layers 31 on the element isolation insulation films 13 in the memory cell array region and the polysilicon layer forming the gate electrodes of the transistors included in the peripheral circuit are simultaneously formed in one process by patterning the same polysilicon layer, thereby achieving the simplification of the manufacturing process.

Furthermore, in the second embodiment, by grounding the polysilicon layers 31 on the element isolation insulation films 13 provided in the memory cell array region and fixing the potentials thereof to 0V, in the n-channel MOS transistors each including the polysilicon layer 31, the p-type region under the element isolation insulation film 13, and the two n-type impurity regions 12 adjacent to each other over the element isolation insulation film 13, the potentials of the polysilicon layers 31 as the gate electrodes are fixed to 0V. Therefore, the transistor is set to the off state. This ensures the prevention of a current flow between the two n-type impurity regions 12 adjacent to each other over the element isolation insulation film 13.

The other effects of the second embodiment are the same as those of the described first embodiment.

It is noted that the disclosed embodiments are only illustrative in all aspects. The scope of the invention is defined by claims but not by the above descriptions of the embodiments. The claimed invention includes the equivalents of the claimed invention and all modifications within the scope of the claims.

For example, the first and second embodiments are described with an example where the invention is applied to the mask ROM, but the invention is not limited to this and applicable to the other memory than the mask ROM.

Furthermore, in the described first or second embodiment, the plurality of n-type impurity regions are separated by the LOCOS films as the element separation regions, but the invention is not limited to this and the plurality of n-type impurity regions may be separated by the STI (Shallow Trench Isolation) or other element isolation method.

Furthermore, in the described first embodiment, the sense amplifier is configured to output a H level signal when a current higher than a predetermined value inclusive flows through a selected bit line, and to output a L level signal when a current lower than the predetermined value flows through the selected bit line. However, the invention is not limited to this, and the sense amplifier may be configured to output a L level signal when a current higher than a predetermined value inclusive flows through a selected bit line, and to output a H level signal when a current lower than the predetermined value flows through the selected bit line.

The second embodiment is described on a case where the “semiconductor layer” is a polysilicon layer, but it may be a tungsten polycide layer.

In the semiconductor memory device of the invention, the cross-point type memory is configured by disposing diodes including first and second impurity regions in a matrix (a cross-point form). In this case, one memory cell includes one diode, so that the memory cell size is reduced compared with a case where one memory cell includes one transistor.

Furthermore, since the increase of resistance due to the increase of the lengths of the first impurity regions is prevented by connecting wirings to the first impurity regions at predetermined intervals, the reduction of the turn-on speed (turn-off speed) of the word lines is prevented.

Furthermore, since the first plugs and the second plugs are connected with each other without pads interposed therebetween, the wirings are formed so as to extend in the same direction as the direction of word lines on the same side as the interlayer insulation film where the first plugs are formed.

What is claimed is:

1. A semiconductor memory device comprising:
a semiconductor substrate;
a plurality of memory cells, each of the memory cells comprising a first impurity region of a first general conductivity type formed in a surface portion of the semiconductor substrate and a second impurity region of a second general conductivity type formed in a surface portion of the first impurity region;
a plurality of bit lines disposed over the semiconductor substrate; and
a plurality of wiring lines disposed between the bit lines and the semiconductor substrate and connected electrically with corresponding first impurity regions,
wherein a wiring scheme between the bit lines and the second impurity regions represents data stored in the memory device.

2. The semiconductor memory device of claim 1, wherein one of the second impurity regions is connected electrically with a bit line, and another of the second impurity regions is not connected electrically with any bit line.

3. The semiconductor memory device of claim 1, wherein the wiring lines and the first impurity regions extend in a first direction, and the bit lines extend in a second direction that is different from the first direction.

4. The semiconductor memory device of claim 1, further comprising a plurality of first plugs connecting the bit lines and corresponding second impurity regions.

5. The semiconductor memory device of claim 3, wherein the first plugs are disposed under the bit lines and above the wiring lines.

6. The semiconductor memory device of claim 1, further comprising an element isolation insulation film disposed between two adjacent first impurity regions and an interlayer insulation film formed on the element isolation insulation film, wherein the wiring lines are disposed on the interlayer insulation film.

7. The semiconductor memory device of claim 6, further comprising a plurality of second plugs connecting the wiring lines and corresponding first impurity regions.

8. The semiconductor memory device of claim 6, further comprising a semiconductor layer disposed on the element isolation film.

9. The semiconductor memory device of claim 8, wherein the first impurity region extends under the element isolation film where the semiconductor layer is not formed.

10. The semiconductor memory device of claim 8, wherein the semiconductor layer is grounded.

11. The semiconductor memory device of claim 1, further comprising a high concentration contact region of the first general conductivity type formed in each of the first impurity regions, wherein the wiring lines are connected with corresponding contact regions.

12. The semiconductor memory device of claim 1, wherein the second impurity regions are formed in the first impurity regions so as to form junction diodes.

13. A semiconductor memory device comprising:
a semiconductor substrate;
a plurality of word lines disposed on the semiconductor substrate in a first direction;
a first interlayer insulation film disposed on the word lines;
a second interlayer insulation film disposed on the first interlayer insulation film;
a plurality of bit lines disposed on the second interlayer insulation film in a second direction;
a plurality of first plugs formed in the first interlayer insulation film;
a plurality of second plugs formed in the second interlayer insulation film and being in direct contact with corresponding first plugs; and
a plurality of wiring lines disposed on the first insulation film in the first direction, part of each of the wiring lines extending between two adjacent second plugs,
wherein the bit lines and the word lines are connected by corresponding first and second plugs.

14. The semiconductor memory device of claim 13, further comprising a third interlayer insulation film disposed between the second interlayer insulation film and the bit lines, and a third plug formed in the third interlayer insulation film and connected with one of the second plugs.

15. A method of manufacturing a semiconductor memory device, comprising:
forming a plurality of element isolation insulation films extending in a first direction on a semiconductor substrate;
forming a plurality of a first impurity regions of a first general conductive type by ion implantation of impurities using the element isolation insulation films as a mask;
forming a first interlayer insulation film so as to cover the element isolation films and the first impurity regions;
forming a first contact hole in the first interlayer insulation film in each of regions corresponding to the first impurity regions;
forming a plurality of second impurity regions of a second general conductive type in the first impurity regions by ion implantation of impurities through the first contact holes;
forming first plugs in the first contact holes;
forming a wiring line on the first interlayer insulation film in a longitudinal direction of the first impurity regions;
forming a second interlayer insulation film on the first interlayer insulation film and the wiring line;
forming a second contact hole in the second interlayer insulation film in a region corresponding to each of the first contact holes;
forming second plugs the second contact holes so as to be connected with corresponding first plugs;
forming pad layers connected with corresponding second plugs on the second interlayer insulation film,
forming a third interlayer insulation film on the second interlayer insulation film and the pad layers;
forming a third contact hole in the third interlayer insulation film in a region corresponding to one of the second contact holes;
forming a third plug in the third contact hole; and
forming a bit line in a direction to cross the first impurity regions and connected with the third plug.

16. The method of claim 15, wherein the first plugs and the second plugs are in direct contact.

17. The method of claim 15, further comprising forming a semiconductor layer on one of the element isolation insulation films.

18. The method of claim 15, further comprising forming a high concentration contact region of the first general conductive type in each of the first impurity regions by ion implantation of impurities through another contact holes.
